(19) United States
(12) Patent Application Publication
(10) Pub. No.: US 2007/0272669 A1
(43) Pub. Date: Nov. 29, 2007

(54) Laser Multiplexing

(76) Inventors: Andrew James Comley, Newbury (GB); Samir Shakir Ellwi, Crawley (GB); Nicolas Hay, East Grinstead (GB); Matthew Henry, Crawley (GB)

Correspondence Address: REINHART BOERNER VAN DEUREN S.C.;ATTN: LINDA KASULKE, DOCKET COORDINATOR, 1000 NORTH WATER STREET, SUITE 2100, MILWAUKEE, WI, 53202, US

(21) Appl. No.: 10/589,926

(22) PCT Filed: Feb. 21, 2005
(86) PCT No.: PCT/GB05/00608

§ 371 Date: May 24, 2007

(30) Foreign Application Priority Data
Feb. 20, 2004 (GB) 0403865.9

(51) Int. Cl. G03F 7/20

(52) U.S. Cl. 219/121.76

(57) ABSTRACT

A laser multiplexing system and method for use with high power pulsed lasers in Extreme Ultraviolet Lithography is disclosed. In a first embodiment, a high power EUV laser multiplexing element for laser produced plasma generation has a compound lens with at least two focusing elements arranged to focus at least two respective laser beams to a focal point on a common workpiece. In a second embodiment, a laser multiplexing apparatus has at least two pulsed laser sources for generating pulsed laser beams and a temporal multiplexing element arranged to temporally interleave at least two pulsed laser beams. In a third embodiment, a laser multiplexing assembly comprises a beam shaping element in which the beam shaping element is arranged to direct a first laser beam along an axis common with a second laser beam axis onto a common focusing element arranged about the common axis.

The invention relates to laser multiplexing for example in high power pulsed lasers.

One area in which laser multiplexing is required is Extreme Ultraviolet Lithography (EUVL) which is considered to be one of the most attractive candidates to succeed conventional optical lithography in the coming years. This will permit reduction of structure sizes in semiconductor devices to less than 30 nm. To enable this technology, a light source is required that emits in the spectral range around 13.5 nm. The Laser Produced Plasma (LPP) EUV source described for example in US2002070353 and WO0219781A1 has great potential to be the future source for EUV lithography, and offers several advantages over discharge-based EUV sources. These advantages can be summarised as: power scalability through tuning of lasers parameters, low debris, pulse-to-pulse stability (optimum dose control), flexibility in dimensions, spatial stability, minimal heat load and large solid angle of collection.

The main requirements for the LPP EUV source are the availability of a refreshable, efficient target as well as high laser repetition rate, high peak intensity and high average laser power on the target. In order to generate optimum conversion efficiency (CE) from laser light to EUV radiation (particularly wavelengths in the vicinity of 13.5 nm), peak intensity (I) on Xe target is required to be in the range 10¹¹-10¹³ W/cm²:
I(W/cm²)=E_{L}/(Aτ) (1)

where E_{L} is the laser pulse energy (joules), A is the focal spot area of the laser beam on target (cm²) and τ is the laser pulse duration (seconds).

Although it is trivial in order to obtain higher powers to combine two highly polarised lasers into one co-linear beam using a polarising beam splitter and polarisation rotation optics (waveplates), this technique cannot combine more than two lasers and cannot be applied to unpolarised lasers.

In one approach known as Master Oscillator Power Amplifier (MOPA), a single large, complex laser system is employed in order to satisfy the input power requirements. Scale-up is achieved for instance by adding amplifier modules after the laser oscillator in order to boost output power. However various problems arise with this system. Firstly, limited flexibility is offered in terms of scalability. Secondly, if a fault occurs on one of the amplifier modules, the complete EUV system is shut down.

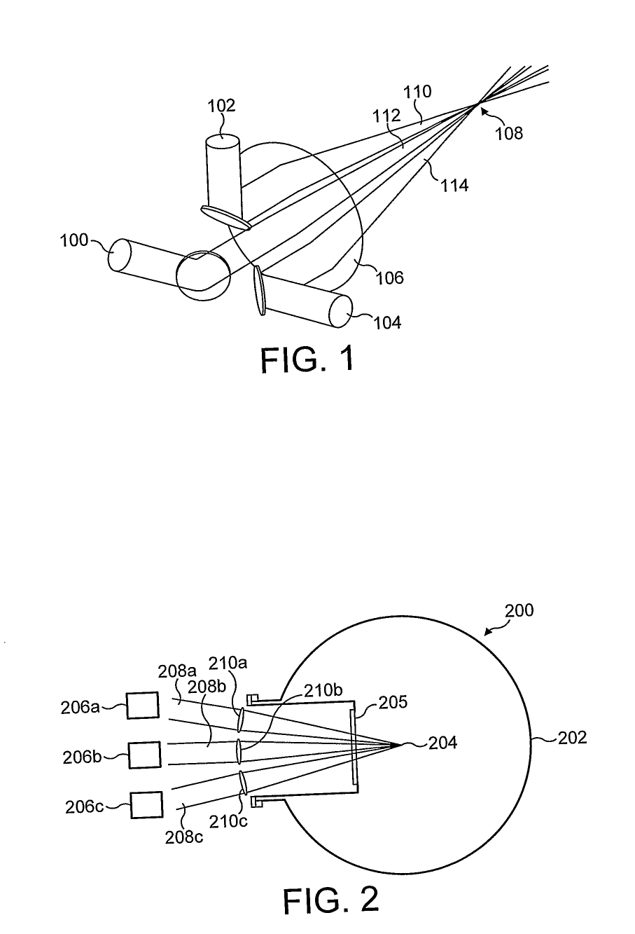

In another known approach shown in FIG. 1, the outputs of several smaller laser modules 100, 102, 104 are combined using a single focussing optic 106 in order to achieve the required peak intensity (Equation 1) on target 108 and therefore the optimum conversion efficiency. The focal spots of all beams 110, 112, 114 are ideally equal in size and perfectly overlapped in space to ensure that the required peak intensity is achieved.

However, problems arise with this system as well. For example, the focal spot size of any given beam can depend on its position on the optic's surface if the lens is not of sufficient quality that spherical aberration can be neglected. Furthermore, if the lens diameter needs to be increased for example to accommodate a larger number of laser beams, it becomes increasingly expensive and difficult to manufacture a lens of sufficient quality. Also, in this system off-axis mirrors are employed in order to arrange the beams on the surface of the focussing optic. However, when using off-axis mirrors, it is difficult to arrange the beams to propagate close together (in order to efficiently use the surface area of the focussing element) because mounting hardware such as lens and mirror holders tend to clip sections of beam path.

In a further known approach, multiple laser optics are used. This approach to increasing the pulse energy on target using multiple laser beams has been demonstrated extensively in laser fusion work at the Rutherford laboratory, National Ignition Facility (NIF) and other large-scale laser facilities. The method involves focussing many beams from a variety of angles in order to illuminate the fusion target. Each beam-line employs its own focussing element in order to achieve the desired peak intensity on target. However, in this configuration the beam lines completely surround the target, severely limiting the collection efficiency of any generated EUV radiation.

A further known approach set out in US2002/0090172 describes a semiconductor diode laser multiplexing system for printing and medical imaging purposes whereby beams emitted from discrete laser diodes converge at the entrance of a multimode optical fibre, and propagate through the fibre. However, such an arrangement is not suitable for use with LLP EUV laser multiplexing schemes as the high intensity light pulses required (in the range 10¹¹-10¹³ w/cm²) would destroy the optical fibre. Moreover, fibre optic delivery severely restricts the solid angle of light collection at the fibre entrance and thereby limiting the number of beams that can be multiplexed with such an arrangement.

The invention is set out in the attached claims.

Embodiments of the invention will now be described by way of example with reference to the drawings, of which:

FIG. 1 shows a prior art laser multiplexer;

FIG. 2 shows a schematic diagram of a spatial laser multiplexer according to the invention;

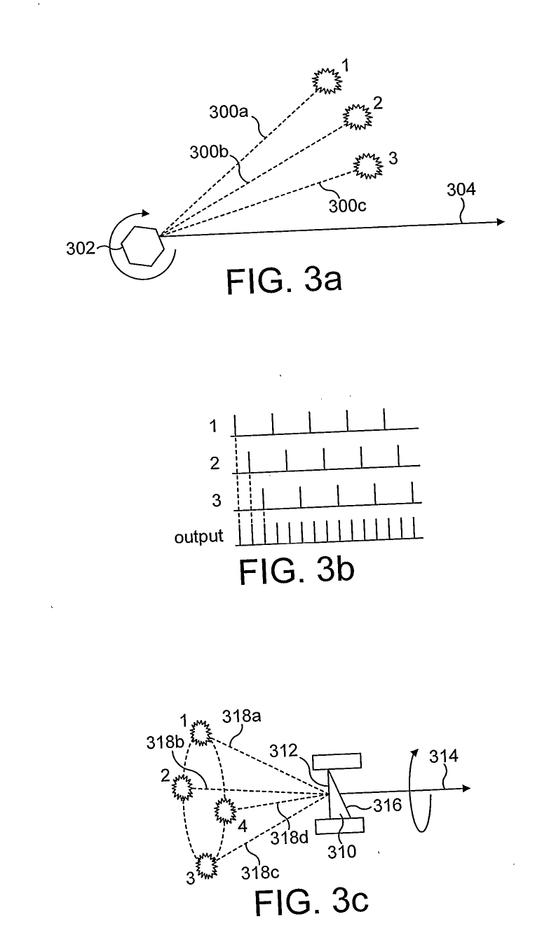

FIG. 3a shows a schematic diagram of a temporal laser multiplexer according to the invention;

FIG. 3b shows a timing diagram for the multiplexer of FIG. 3a;

FIG. 3c shows an alternative temporal multiplexer according to the invention; and

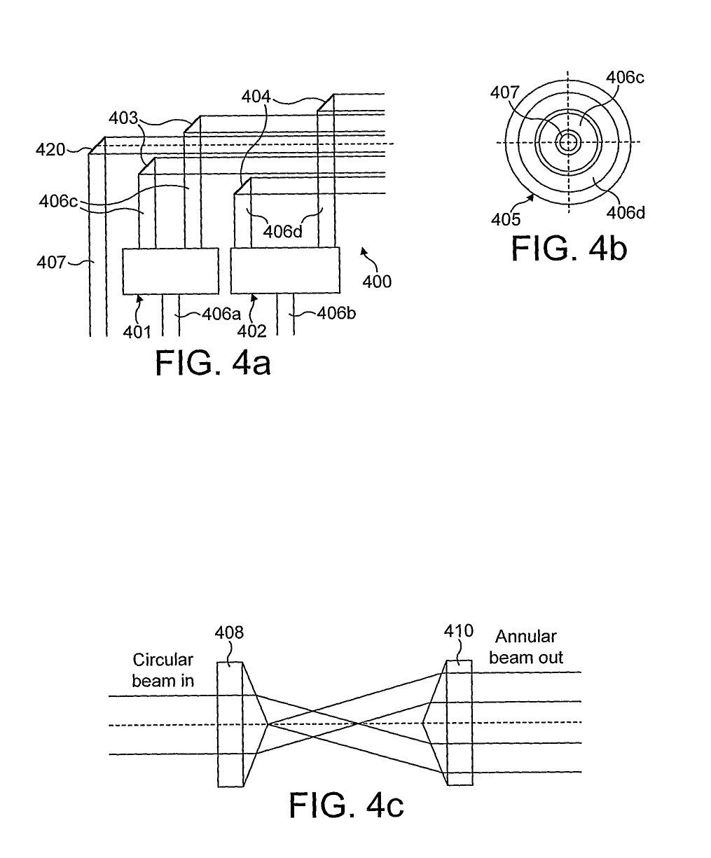

FIGS. 4a, 4b and 4c show a schematic diagram of a further embodiment of the invention.

In a first embodiment of the invention shown in FIG. 2 an LPP EUV system is designated generally 200 and includes an LPP chamber 202 of any appropriate type including a collector (not shown) and a target 204. A plurality of laser sources 206a, 206b, 206c generate laser beams 208a, 208b, 208c. The beams are directed onto an array of respective closely spaced, small lenses 210a, 210b, 210c, forming a so-called ‘fly-eye’ arrangement. Each lens accommodates 1-2 laser beams and the whole optical assembly constitutes a compound lens that focuses N laser beams onto any type of target or workpiece through chamber window 205, particularly for the purpose of generating EUV radiation.

An appropriate laser is a pulsed, diode-pumped solid state laser (e.g. Powerlase model Starlase AO4 Q-switched Nd:YAG laser) providing multi-khz repetition rates and pulses of duration 5-10 ns. A standard single element positive lens (plano-convex, or bi-convex, antireflection coated) would be a suitable element for a ‘fly-eye’ compound lens (e.g. 300 mm focal length, 1″ diameter, fused silica, plano-convex lens with anti-reflection coating for 1064 nm light—CVI Laser LLC, part number PLCX-25.4-154.5-UV-1064). The optical performance could be optimised using any appropriate commercial software package (e.g. Code V from Optical Research Associates)

Combining multiple lasers using the spatial multiplexing method described above offers several advantages over prior art LPP driver arrangements. For example compared to using a single high power laser greater flexibility is offered in terms of scalability. Secondly, if a fault occurs on one of the multiplexed modules, the EUV system can continue to run (albeit at slightly reduced output power).

Compared to a spatial multiplexing scheme involving a single focussing optic, the focal spot size of any given beam does not depend on its position on the optic's surface such that lens quality is less determinative. However, if the lens diameter needs to be increased for example to accommodate a larger number of laser beams, in the fly-eye scheme, smaller, readily available and high quality lenses can be employed in order to minimise the effect of aberrations.

Furthermore, in contrast to systems using multiple independent focussing optics, the fly-eye compound lens gives a larger solid angle in which EUV can be collected as the laser radiation is confined to a narrow cone.

In a second embodiment shown in FIGS. 3a to 3c, the laser power incident on a target is increased using temporal and/or spatial or angular multiplexing to combine several source laser beams into a single, co-propagating output beam of the high repetition rates required for LPP production. The technique may be made independent of the polarisation states of the source laser beams.

A number of source laser beams 300a, 300b, 300c of the type described above are directed at an optical element 302, in this case a rotating mirror or prism which introduces a time-varying angular deviation to the beams. The angle of incidence of each source beam 300a, 300b, 300c upon the deviating element 302 is unique.

Each source laser beam consists of a train of discrete pulses separated in time by the reciprocal of the laser repetition frequency. As can be seen in FIG. 3b which illustrated the system for 3 lasers, the timing of the source lasers is arranged such that their output pulse trains are temporally interleaved and therefore the arrival time of each laser pulse at the deviating element is unique. The time-variation of the deviating element is arranged such that an incident pulse from any of the source lasers is made to propagate along a common output path.

In the case of the rotating reflective prism 302 shown in FIG. 3a, the prism is of hexagonal cross-section, although other polygonal cross-sections could be used providing that the number of reflecting surfaces is an integer multiple of the number of laser beams being multiplexed. Because the prism 302 is rotated, and the source laser beams 300a, 300b, 300c are successively pulsed, a single face of the prism presents a different angle of incidence to each source beam pulse. Accordingly the rate of rotation of the prism can be determined such that the variation in angle of each source beam is effectively compensated such that the beams are all reflected along a common output path 304. The rate of rotation is also selected such that the reflection angle of a pulse between leading and trailing edges is minimised, that is, there is no substantial angular spread caused as a result of pulse dwell time, therefore removing the need for compensatory secondary optics.

It will be appreciated that various alternative arrangements can be provided, for example a reciprocating mirror or the variant shown in FIG. 3c in which a wedge-shaped prism 310 has a source beam input face 312 perpendicular to the direction of the output beam 314 and an output face 316 at an angle to the input face 312. The wedge is rotated such that the output face presents the same angle of incidence to different source laser beams 318a, 318b, 318c, 318d in turn as these are sequentially pulsed. Accordingly, the difference in angle of incidence of each of these beams is once again compensated by the rotating wedge to provide a common output path 314. As the laser pulses are equally separated in time and the wedge is rotating at a constant angular velocity the laser sources are equally separated in angle. Alternatively the output face may be perpendicular to the direction of the output beam and the input face may be at an angle to the output face or both faces may be at an angle to the direction of the output beam.

The resulting beam is temporally and angularly multiplexed with an average power of N×(source average power) and a repetition frequency of N×(source repetition frequency) where N is the number of sources. A beam multiplexed in this way may be further combined (e.g. by use of spatial multiplexing as discussed above).

As a result of this arrangement polarisation independent multiplexing for multiple lasers can be achieved.

Furthermore as a result of this arrangement the average power scaling up can be controlled independently from peak intensity on target i.e. the average power on target can be increased without increasing the peak intensity on the target.

In a further embodiment, generally designated 400, shown in FIG. 4a and 4b the system comprises beam shaping elements 401 and 402 for forming a beam of annular cross-section and plane annular mirrors 403 and 404 and a common focusing element 405. The annular mirrors and common focusing elements are arranged about a common longitudinal axis. A plurality of lasers generate laser beams 406a, 406b and 407. A first and second of the plurality of laser beams 406a, 406b are directed onto respective beam shaping elements 401, 402 to produce respective annular output beams 406c, 406d (shown in side cross-section). Each annular output beam 406c, 406d is directed to a common focusing element 405 using annular mirrors 403, 404 (shown in side-cross-section) angled to the beam direction such that the directed beam propagates along a common axis. An additional laser beam 407 is directed to the common focusing element by a plane mirror 420. The annular mirrors and plane mirror are orientated substantially parallel to each other, and are arranged to form a concentric beam pattern at the common focusing element. The common focussing element 405 is shown in end view in FIG. 4b on which the spatially separated annular beams can be seen incident concentrically.

Preferably, each beam shaping element is formed of a pair of conical or “axicon” lenses of the type described at www.sciner.com/Opticsland/axicon.htm as shown in FIG. 4c. In this arrangement, the circular input beam is divided by a first axicon lens 408 to produce a divergent annular shaped beam which is incident on second axicon lens 410, to produce a substantially collimated annular output beam. Alternatively, diffractive optics such as diffraction gratings could be employed to produce the annular shaped beams.

Three beams have been shown in FIG. 4a but in principle any number of beams could be multiplexed in this way, the maximum number of beams being ultimately limited by the aperture of the focussing element.

Combining multiple lasers using beam shaping techniques of the type described above offers several advantages over prior art arrangements. For example, by using annular beams which propagate along a common axis, the need for off-axis mirrors and the alignment problems associated therewith are removed.

It will be appreciated that the temporal or spatial multiplexing schemes can be coupled in any appropriate manner whereby temporally interleaved or overlapping beams can be incident on a common “channel” spatially multiplexed with other such beams.

The combination of spatial and temporal multiplexing allows the laser average power on the EUV target to be scaled up, as a result increasing the EUV average power output. This is achieved as follows from equation 1: laser power intensity on target is increased until optimum conversion efficiency of EUV radiation is achieved, then scaling up the average power is achieved by temporal multiplexing.

It will be appreciated that individual elements and steps from the various embodiments can be combined or juxtaposed as appropriate. Any appropriate laser can be used, together with any appropriate optical elements such as reflective, refractive or diffractive deviation elements to achieve the desired effects. Also the approach can be used to obtain high powers for any appropriate application and continuous lasers can be used where appropriate. The approaches, when combined, can be combined in any order.

1. A laser multiplexing apparatus comprising a compound lens comprising at least two focusing elements arranged to focus at least two respective laser beams to a focal point on a common workpiece.

2. An element as defined in claim 1, in which the compound lens comprises an array of lenses.

3. A laser including an element as defined in claim 1.

4. A method of multiplexing laser beams comprising temporally interleaving at least two pulsed laser beams such that said beams are multiplexed independent of their state of polarization.

5. A method as defined in claim 4, in which at least two laser beams are spatially separated and in which a variable deviation element focuses the laser beams onto a common target area on a workpiece.

6. A method as defined in claim 4, in which the variable deviation element is moveable so as to focus the temporally interleaved beams onto the common target area on a workpiece.

7. A method of multiplexing laser beams comprising the steps, in any order, of:
spatially multiplexing laser pulses onto a common workpiece; and
temporally interleaving at least some of the spatially multiplexed pulses.

8. A method as defined in claim 7, further comprising temporally overlapping at least some of the pulses.

9. A laser multiplexing apparatus comprising:
at least two pulsed laser sources for generating pulsed laser beams; and
a temporal multiplexing element arranged to temporally interleave at least two pulsed laser beams.

10. An apparatus as defined in claim 9, in which the temporal multiplexing element comprises a variable deviation element.

11. An apparatus as defined in claim 10, in which the variable deviation element comprises a moveable reflector or wedge.

12. An apparatus as defined in claim 10, in which the variable deviation element comprises a moveable refractor.

13. An apparatus as defined in claim 10, in which the variable deviation element comprises a moveable diffractive element.

14. An apparatus as defined in claim 10, in which the variable deviation element has a number of reflective surfaces being an integer number of the number of laser sources being multiplexed.

15. An apparatus as defined in claim 9, further comprising a laser multiplexing element as defined in claim 1.

16. A high power laser produced plasma generation apparatus comprising:
a laser as defined in claim 1; and
an apparatus defined in claim 9.

17. A laser plasma production apparatus comprising:
a laser as defined in claim 1; and
a laser apparatus as defined in claim 9.

18. A method of multiplexing laser beams comprising the steps of:
directing pulsed laser light from two or more independent lasers onto a movable deviation element; and
moving said deviation element at a rate such that deviation of a laser pulse between lead and trailing edges is minimized.

19. A laser multiplexing assembly comprising a beam shaping element in which the beam shaping element is arranged to direct a first laser beam along an axis common with a second laser beam axis onto a common focusing element arranged about said common axis.

20. An assembly as defined in claim 19, in which the beam shaping element is arranged to spatially separate the first and second beams.

21. An assembly as defined in claim 19, in which the beam shaping element is formed of a lens.

22. An assembly as defined in claim 21, in which the lens is an axicon lens.

23. A method of multiplexing laser beams comprising the steps of directing a first laser beam along an axis common with a second laser beam axis onto a common focusing element arranged about said common axis.

24. A laser multiplexing apparatus comprising:
a plurality of laser sources each of which generates a laser beam along an axis that is laterally and/or angularly spaced apart from the axes of all other laser beams; and
a temporal multiplexing element that is configured and arranged to temporally interleave the laser beams from the plurality of sources such that the plurality of laser beams all propagate close together.

25. A laser multiplexing apparatus as defined in claim 24, wherein the temporal multiplexing element comprises:
an array of respective closely spaced, small lenses forming a “fly-eye” arrangement.

26. A laser multiplexing apparatus as defined in claim 24, wherein the temporal multiplexing element comprises:
a rotating mirror or prism which introduces a time-varying angular deviation to the laser beams.

27. A laser multiplexing apparatus as defined in claim 24, wherein the temporal multiplexing element comprises:
a wedge-shaped prism that is rotated such that an output face of the wedge-shaped prism presents the same angle of incidence to the laser beams in turn as they are sequentially pulsed.

28. A laser multiplexing apparatus as defined in claim 24, wherein the temporal multiplexing element comprises:
a plurality of beam shaping elements that have the plurality of laser beams respectively focused thereupon to produce respective coaxial circular output beams; and
a common focusing element that produces a substantially collimated annular output beam from the circular annular output beams.
